(19) United States
(12) Patent Application Publication
(10) Pub. No.: US 2026/0082626 A1
(43) Pub. Date: Mar. 19, 2026

(54) SEMICONDUCTOR DEVICE AND METHOD FOR MANUFACTURING

(71) Applicants: Kabushiki Kaisha Toshiba, Tokyo (JP); Toshiba Electronic Devices & Storage Corporation, Tokyo (JP)

(72) Inventors: Tsuyoshi KACHI, Kanazawa Ishikawa (JP); Hiroaki KATOU, Nonoichi Ishikawa (JP)

(21) Appl. No.: 18/977,191

(22) Filed: Dec. 11, 2024

(30) Foreign Application Priority Data
Sep. 13, 2024 (JP) 2024-159354

(51) Int. Cl. H10D 30/66; H10D 30/01; H10D 62/10; H10D 64/00; H10D 64/01; H10D 64/23

(52) U.S. Cl. CPC H10D 30/668; H10D 30/0295; H10D 30/0297; H10D 62/127; H10D 64/01; H10D 64/117; H10D 64/2527

(57) ABSTRACT

A semiconductor device includes first and second electrodes, a semiconductor layer, a plurality of third electrodes, a fourth electrode, a first insulating layer, and a wiring part. The semiconductor layer is located between the first electrode and the second electrode. The semiconductor layer includes first to third semiconductor regions. The plurality of third electrodes faces the first semiconductor region via a first insulating part. The fourth electrode includes a part positioned between two mutually-adjacent third electrodes. The fourth electrode faces the second semiconductor region via a second insulating part. The first insulating layer is located on the semiconductor layer. The wiring part is located inside the first insulating layer in the cell region. The wiring part extending along the fourth electrode over the fourth electrode. The wiring part is finer than the fourth electrode. The wiring part is electrically connected with the fourth electrode.

### CROSS-REFERENCE TO RELATED APPLICATIONS

This application is based upon and claims the benefit of priority from Japanese Patent Application No. 2024-159354, filed on Sep. 13, 2024; the entire contents of which are incorporated herein by reference.

### FIELD

Embodiments relate to a semiconductor device and a method for manufacturing.

### BACKGROUND

In a semiconductor device such as a power MOSFET (Metal-Oxide-Semiconductor Field-Effect Transistor) or similar devices that includes a transistor, reducing the gate resistance of the transistor can, for example, increase the switching speed.

### BRIEF DESCRIPTION OF THE DRAWINGS

FIG. 1 is a schematic plan view illustrating a semiconductor device according to an embodiment;

FIG. 2 is a schematic view illustrating the semiconductor device according to the embodiment;

FIG. 3 is a schematic view illustrating the semiconductor device according to the embodiment;

FIG. 4 is a schematic view illustrating the semiconductor device according to the embodiment;

FIG. 5 is a schematic view illustrating the semiconductor device according to the embodiment;

FIG. 6 is a schematic view illustrating the semiconductor device according to the embodiment;

FIG. 7 is a schematic view illustrating the semiconductor device according to the embodiment;

FIG. 8 is a schematic view illustrating the semiconductor device according to the embodiment;

FIG. 9 is a schematic view illustrating the semiconductor device according to the embodiment;

FIGS. 10A and 10B are schematic cross-sectional views illustrating a method for manufacturing the semiconductor device according to the embodiment;

FIGS. 11A and 11B are schematic cross-sectional views illustrating a method for manufacturing the semiconductor device according to the embodiment;

FIGS. 12A and 12B are schematic cross-sectional views illustrating a method for manufacturing the semiconductor device according to the embodiment;

FIG. 13 is a schematic view illustrating a semiconductor device according to a modification of the embodiment;

FIG. 14 is a schematic view illustrating a semiconductor device according to a modification of the embodiment;

FIG. 15 is a schematic view illustrating a semiconductor device according to a modification of the embodiment;

FIG. 16 is a schematic view illustrating the semiconductor device according to the modification of the embodiment;

FIG. 17 is a schematic view illustrating the semiconductor device according to the modification of the embodiment;

FIG. 18 is a schematic view illustrating the semiconductor device according to the modification of the embodiment;

FIGS. 19A and 19B are schematic cross-sectional views illustrating a method for manufacturing the semiconductor device according to the modification;

FIG. 20 is a schematic view illustrating another semiconductor device according to the embodiment;

FIG. 21 is a schematic view illustrating another semiconductor device according to the embodiment;

FIG. 22 is a schematic view illustrating another semiconductor device according to the embodiment;

FIG. 23 is a schematic view illustrating another semiconductor device according to the embodiment;

FIG. 24 is a schematic view illustrating another semiconductor device according to the embodiment; and

FIG. 25 is a schematic view illustrating another semiconductor device according to the embodiment.

### DETAILED DESCRIPTION

A semiconductor device according to one embodiment, includes a first electrode, a second electrode, a semiconductor layer, a plurality of third electrodes, a fourth electrode, a first insulating layer, and a wiring part. The second electrode is positioned above the first electrode. The semiconductor layer is located between the first electrode and the second electrode. The semiconductor layer includes a first semiconductor region, a second semiconductor region, and a third semiconductor region. The first semiconductor region is of a first conductivity type. The second semiconductor region is located on the first semiconductor region. The second semiconductor region is of a second conductivity type. The third semiconductor region is located on the second semiconductor region. The third semiconductor region is electrically connected with the second electrode. The third semiconductor region is of the first conductivity type. The plurality of third electrodes is arranged in a cell region in which the second electrode is located. The plurality of third electrodes faces the first semiconductor region via a first insulating part. The fourth electrode includes a part positioned between two mutually-adjacent third electrodes among the plurality of third electrodes. The fourth electrode faces the second semiconductor region via a second insulating part. The first insulating layer is located on the semiconductor layer. The wiring part is located inside the first insulating layer in the cell region. The wiring part extending along the fourth electrode over the fourth electrode. The wiring part is finer than the fourth electrode. The wiring part is electrically connected with the fourth electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the following description and drawings, the notations of n⁺ and n⁻ indicate relative levels of the impurity concentrations. In other words, a notation marked with “+” indicates that the impurity concentration is relatively greater than that of a notation not marked with either “+” or “−”, and a notation marked with “−” indicates that the impurity concentration is relatively less than that of a notation without any mark. When both a p-type impurity and an n-type impurity are included in each region, these notations indicate relative levels of the net impurity concentrations after the impurities are compensated.

In the examples described below, a first conductivity type is the n-type, and a second conductivity type is the p-type. In the embodiments described below, each embodiment may be implemented by inverting the n-type and the p-type of each semiconductor region.

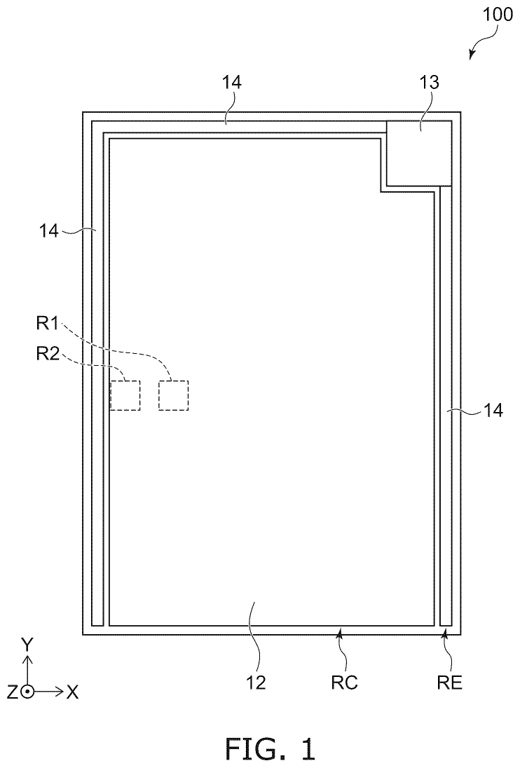

FIG. 1 is a schematic plan view illustrating a semiconductor device according to an embodiment.

In the description of the embodiments, an X-direction, a Y-direction, and a Z-direction that are orthogonal to each other are used. For example, when viewed from above (when viewed along the Z-direction) as illustrated in FIG. 1, the semiconductor device 100 according to the embodiment is a rectangle having sides extending in the X-direction and Y-direction.

The semiconductor device 100 is, for example, a MOSFET. A source electrode 12, a gate pad 13, and a gate wiring part 14 are located at the upper surface side of the semiconductor device 100. For example, the source electrode 12, the gate pad 13, and the gate wiring part 14 are arranged in the same X-Y plane.

In the semiconductor device 100, a cell region RC in which the source electrode 12 is located is set, and a peripheral region RE that is positioned at the periphery of the cell region RC in the X-Y plane is set. As described below, the cell region RC is a region in which transistors are formed in the semiconductor layer. The source electrode 12 extends in the X-Y plane and covers the entire cell region RC. The gate pad 13 and the gate wiring part 14 are not located in the cell region RC. The source electrode 12 is insulated from the gate pad 13 and the gate wiring part 14.

The peripheral region RE is arranged with the cell region RC in directions in the X-Y plane. The peripheral region RE may include, for example, a termination region of the semiconductor device 100. The termination region includes the outer edge of the semiconductor layer when viewed in plan and is a region along the outer edge. The gate wiring part 14 and the gate pad 13 are located in the peripheral region RE and may surround, for example, the source electrode 12. The gate wiring part 14 extends in the X-direction or Y-direction and is electrically connected with the gate pad 13. In the example, the gate pad 13 is located at a corner part of the rectangle of the semiconductor device 100. The source electrode 12 is not located 20 in the peripheral region RE.

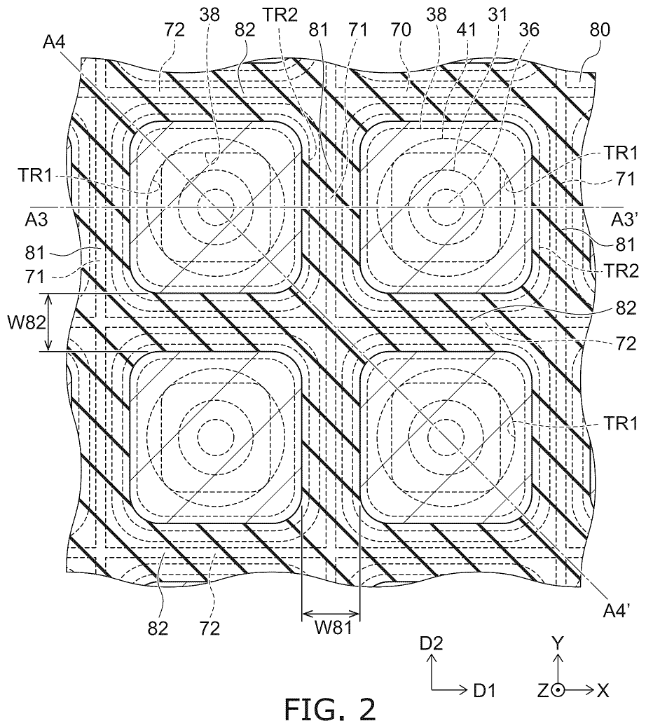

FIGS. 2 to 5 are schematic views illustrating the semiconductor device according to the embodiment.

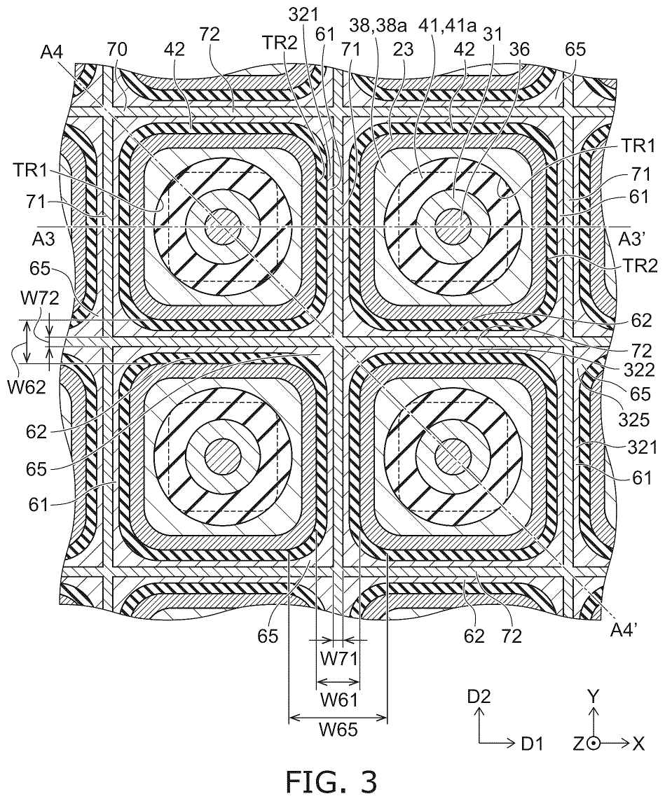

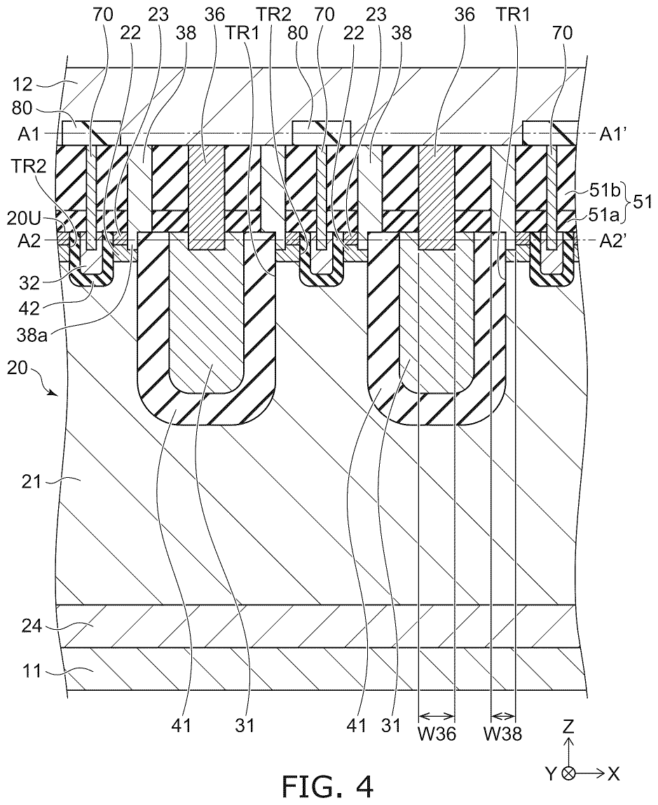

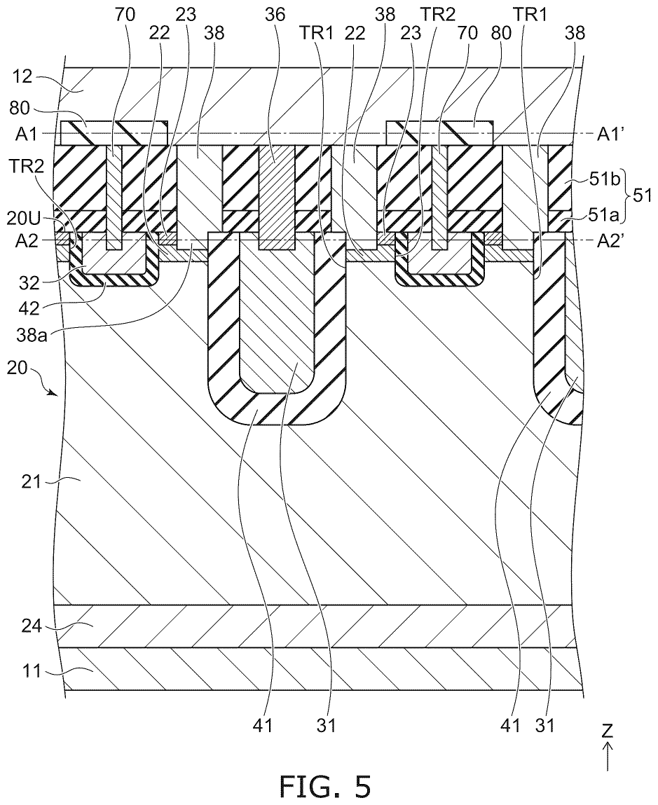

FIGS. 2 to 5 illustrate the structure inside the cell region RC (a region R1 illustrated in FIG. 1). FIGS. 2 and 3 illustrate the planar layout. The hatching of FIG. 2 corresponds to a cross section along line A1-A1′ shown in FIG. 4; and the hatching of FIG. 3 corresponds to a cross section along line A2-A2′ shown in FIG. 4. FIG. 4 illustrates a cross section along line A3-A3′ shown in FIGS. 2 and 3. FIG. 5 illustrates a cross section along line A4-A4′ shown in FIGS. 2 and 3.

For example, as illustrated in FIG. 4, the semiconductor device 100 includes a drain electrode 11 (a first electrode), the source electrode 12 (a second electrode), and a semiconductor layer 20. The semiconductor layer 20 is positioned between the drain electrode 11 and the source electrode 12.

In the description of the embodiments, the direction from the drain electrode 11 toward the source electrode 12 is taken as the Z-direction (a first direction). The upper surface and lower surface of the semiconductor layer 20 (the semiconductor substrate) are along the X-Y plane perpendicular to the Z-direction. For convenience, the direction from the drain electrode 11 toward the source electrode 12 is called “up”, and the opposite direction is called “down”. These directions are based on the relative positional relationship between the drain electrode 11 and the source electrode 12, and are independent of the direction of gravity.

The semiconductor layer 20 includes a drain region 24, a drift region 21 (a first semiconductor region), a base region 22 (a second semiconductor region), and a source region 23 (a third semiconductor region).

The drain region 24 is a semiconductor region of a first conductivity type (the n⁺-type). The drain region 24 is located on the drain electrode 11 and electrically connected with the drain electrode 11.

The drift region 21 is a semiconductor region of the first conductivity type (the n⁻-type) located on the drain region 24. The n-type impurity concentration (atoms/cm³) in the drift region 21 is less than the n-type impurity concentration (atoms/cm³) in the drain region 24.

The base region 22 is a semiconductor region of a second conductivity type (the p-type) located on a portion of the drift region 21.

The source region 23 is a semiconductor region of the first conductivity type (the n⁺-type) located on a portion of the base region 22. The upper end of the source region 23 is positioned at an upper surface 20U (the surface at the source electrode 12 side) of the semiconductor layer 20. The n-type impurity concentration (atoms/cm³) in the source region 23 is greater than the n-type impurity concentration in the drift region 21.

For example, the drift region 21 and the drain region 24 are located over the cell region RC and the peripheral region RE; and the base region 22 and the source region 23 are located in the cell region RC.

For example, as illustrated in FIG. 4, multiple FP trenches TR1 (first trenches) and a gate trench TR2 (a second trench) are provided in the upper surface 20U of the semiconductor layer 20.

The FP trench TR1 extends from the upper surface 20U to the drift region 21 in the Z-direction. A FP insulating part 41 (a first insulating part) and a FP electrode 31 (a third electrode) are located inside the FP trench TR1. The FP insulating part 41 covers the inner wall (the side surface and the bottom surface) of the FP trench TR1. The FP insulating part 41 contacts the drift region 21 and the base region 22.

The FP electrode 31 is a field plate. The FP electrode 31 is positioned at the inner side of the FP insulating part 41 inside the FP trench TR1. In other words, the FP insulating part 41 is located between the FP electrode 31 and the semiconductor layer 20. The lower surface and side surface of the FP electrode 31 contact the FP insulating part 41. The FP electrode 31 is insulated from the semiconductor layer 20 by the FP insulating part 41. The FP electrode 31 includes a part arranged with a portion of the drift region 21 in directions in the X-Y plane. In other words, the FP electrode 31 faces a portion of the drift region 21 via the FP insulating part 41.

The gate trench TR2 includes a part positioned between two mutually-adjacent FP trenches TR1 (FP trenches TR1 that are most proximate to each other among the multiple FP trenches TR1). The gate trench TR2 extends from the upper surface 20U of the semiconductor layer 20 to the drift region 21 in the Z-direction. The gate trench TR2 is shallower than the FP trench TR1.

A gate insulating part 42 (a second insulating part) and a gate electrode 32 (a fourth electrode) are located inside the gate trench TR2. The gate insulating part 42 covers the inner wall (the side surface and the bottom surface) of the gate trench TR2. The gate insulating part 42 contacts the drift region 21, the base region 22, and the source region 23.

The gate electrode 32 is positioned at the inner side of the gate insulating part 42 inside the gate trench TR2. In other words, the gate insulating part 42 is located between the gate electrode 32 and the semiconductor layer 20. The lower surface and side surface of the gate electrode 32 contact the gate insulating part 42. The gate electrode 32 is insulated from the semiconductor layer 20 by the gate insulating part 42. The gate electrode 32 includes a part arranged with a portion of the drift region 21, the base region 22, and a portion of the source region 23 in directions in the X-Y plane. In other words, the gate electrode 32 faces the drift region 21, the base region 22, and the source region 23 via the gate insulating part 42. The FP electrode 31 extends to a deeper position than the gate electrode 32.

For example, as illustrated in FIG. 4, an insulating layer 51 (a first insulating layer) that extends along the X-Y plane is located on the upper surface 20U of the semiconductor layer 20. The insulating layer 51 is located on the upper surface 20U, the upper surface of the FP insulating part 41, and the upper surface of the gate insulating part 42 in contact with the upper surface 20U, the upper surface of the FP insulating part 41, and the upper surface of the gate insulating part 42. In the example, the insulating layer 51 includes a first layer 51a, and a second layer 51b stacked on the first layer 51a. The insulating layer 51 is not limited thereto; the insulating layer 51 may include three or more stacked layers, or may be made of one layer.

A gate wiring part 70 that is electrically connected with the gate electrode 32 is located inside the insulating layer 51 inside the cell region RC. The gate wiring part 70 is positioned directly above the gate trench TR2 and the gate electrode 32. The gate wiring part 70 extends in the Z-direction and extends through the insulating layer 51. That is, the gate wiring part 70 is filled into a slit (a trench) extending through the insulating layer 51 in the Z-direction. The lower end of the gate wiring part 70 contacts the upper surface of the gate electrode 32.

An insulating layer 80 (a second insulating layer) that covers the upper end of the gate wiring part 70 is located on the gate wiring part 70. In the example, the insulating layer 80 contacts the upper end of the gate wiring part 70 and the upper surface of the insulating layer 51. That is, the insulating layer 80 is formed to protrude upward from the upper surface of the insulating layer 51. The source electrode 12 is located on the insulating layers 51 and 80 and contacts the insulating layers 51 and 80. The source electrode 12 covers and contacts the side surface and upper surface of the insulating layer 80. The source electrode 12 is insulated from the gate wiring part 70 by the insulating layer 80. The thickness (the Z-direction length) of the insulating layer 80 may be less than the thickness of the insulating layer 51. The flatness of the source electrode 12 can be improved by making the insulating layer 80 thin.

A source contact 38 (a second contact) is located on the base region 22 and the FP insulating part 41. The source contact 38 extends in the Z-direction and extends through the insulating layer 51. That is, the source contact 38 is located inside a slit extending through the insulating layer 51. The source contact 38 contacts the lower surface of the source electrode 12 and the source region 23 (and the base region 22). As a result, the source contact 38 electrically connects the source electrode 12 and the source region 23. The source contact 38 may be separated from the FP electrode 31. In the example, a portion of the source contact 38 is on the FP insulating part 41. As a result, for example, the width of the source contact 38 can be ensured even when the trenches are densely arranged.

A FP contact 36 (a first contact) is located on the center of the FP electrode 31. The FP contact 36 extends in the Z-direction and extends through the insulating layer 51. That is, the FP contact 36 is located inside a contact hole that extends through the insulating layer 51. The FP contact 36 contacts the FP electrode 31 and the lower surface of the source electrode 12. As a result, the FP contact 36 electrically connects the source electrode 12 and the FP electrode 31.

In the example, the height (the Z-direction position) of the upper end of the gate wiring part 70 is equal to the height of the upper end of the FP contact 36 and the height of the upper end of the source contact 38. The height of the upper end of the gate wiring part 70 may be equal to the height of the upper surface of the insulating layer 51. In other words, for example, the upper end of the gate wiring part 70, the upper end of the FP contact 36, the upper end of the source contact 38, and the upper surface of the insulating layer 51 are coplanar. The height of the lower end of the gate wiring part 70 may be equal to the height of the lower end of the FP contact 36 and the height of the lower end of the source contact 38.

As illustrated in FIG. 3, the source region 23 (and a portion of the base region 22) surrounds the outer perimeter of a lower end part 38a of the source contact 38 in the X-Y plane and contacts the outer perimeter surface of the lower end part 38a. The lower end part 38a of the source contact 38 surrounds the outer perimeter of an upper end part 41a of the FP insulating part 41 in the X-Y plane and contacts the outer perimeter surface of the upper end part 41a. The upper end part 41a surrounds the outer perimeter of the FP electrode 31.

In FIG. 2, the positions of the FP contact 36, the FP electrode 31, the FP insulating part 41, the FP trench TR1, the source contact 38, the gate trench TR2, and the gate wiring part 70 when viewed in plan from above are illustrated by broken lines. For example, as illustrated in FIG. 2, the multiple FP trenches TR1 are arranged in the X-Y plane in the cell region RC. More specifically, the multiple FP trenches TR1 are arranged in a first arrangement direction D1 and a second arrangement direction D2. The first arrangement direction D1 is the direction of the shortest line connecting one FP trench TR1 and the FP trench TR1 most proximate to the one FP trench TR1. The multiple FP electrodes 31 (the FP trenches TR1) are positioned at the intersections of a lattice shape or a mesh shape in which lines extending in the first arrangement direction D1 and lines extending in the second arrangement direction D2 cross when viewed in plan. In the example, the first arrangement direction D1 is the X-direction; and the second arrangement direction D2 is the Y-direction. Accordingly, the multiple FP electrodes 31 are positioned at vertices of squares when viewed in plan. According to the embodiment, the first arrangement direction D1 and the second arrangement direction D2 are not necessarily orthogonal.

For example, the planar shapes of the FP electrode 31 and the FP insulating part 41 are circular. The planar shapes of the FP electrode 31 and the FP insulating part 41 may be a regular polygon such as a square, a regular hexagon, etc. A regular polygon includes a regular polygon with rounded corners. The FP electrodes 31 are located at the centers of the FP trenches TR1. The FP contacts 36 have cylindrical shapes positioned at the centers of the FP electrodes 31.

As illustrated in FIG. 3, the gate trench TR2 includes a first extension part 61, a second extension part 62, and an intersection part 65 in the cell region RC.

The first extension part 61 is positioned between two FP trenches TR1 adjacent to each other in the first arrangement direction D1; and the first extension part 61 extends in a direction perpendicular to the first arrangement direction D1. For example, the first extension part 61 has a constant width W61 (the length in the direction perpendicular to the first arrangement direction D1).

The second extension part 62 is positioned between two FP trenches TR1 adjacent to each other in the second arrangement direction D2; and the second extension part 62 extends in a direction perpendicular to the second arrangement direction D2. For example, the second extension part 62 has a constant width W62 (the length in the direction perpendicular to the second arrangement direction D2). The width W62 may be equal to the width W61.

The intersection part 65 is a part at which the first extension part 61 and the second extension part 62 cross. In other words, the intersection part 65 connects the end of the first extension part 61 and the end of the second extension part 62. For example, the planar shape of the gate trench TR2 is a mesh shape. In the example, the gate trench TR2 has a lattice shape in which a part extending in the first arrangement direction D1 and a part extending in the second arrangement direction D2 cross at the intersection part 65. In other words, the intersection parts 65 are positioned at the vertices of the square; and two first extension parts 61 and two second extension parts 62 are positioned at the four sides of the square. One FP trench TR1 is located inside the square; and the FP electrode 31 is positioned at the center of the square.

For example, a width W65 (the length in the direction perpendicular to the first arrangement direction D1) of the intersection part 65 is greater than the width W61 of the first extension part 61. The width W65 of the intersection part 65 is greater than the width W62 of the second extension part 62. The width in the second arrangement direction D2 of the intersection part 65 may be equal to the width W65 in the first arrangement direction D1.

For example, the width of the intersection part 65 gradually widens continuously from the first extension part 61 or the second extension part 62. Accordingly, the planar shape of the region surrounded with the first extension part 61, the second extension part 62, and the intersection part 65 is a polygon (in the example, a square) with rounded corners. The planar shape is not limited to the planar shape described above; according to the embodiment, the width W65 of the intersection part 65 may be equal to the width W61 of the first extension part 61.

The thickness of the gate insulating part 42 inside the gate trench TR2 may be substantially constant when viewed in plan. The gate electrode 32 includes an extension part (a first extension part 321) that is located inside the first extension part 61 and extends similarly to the first extension part 61, an extension part (a second extension part 322) that is located inside the second extension part 62 and extends similarly to the second extension part 62, and a part 325 that is located inside the intersection part 65. Similarly to the gate trench TR2, the gate electrode 32 has a mesh shape or a lattice shape. The width of the gate electrode 32 inside the intersection part 65 may be greater than the width of the gate electrode 32 inside the first extension part 61 or inside the second extension part 62. By setting the gate trench TR2 and the gate electrode 32 inside the gate trench TR2 to have a mesh shape or a lattice shape, a large region that operates as a transistor can be ensured.

The gate wiring part 70 extends along the gate electrode 32 over the gate electrode 32. For example, similarly to the planar shape of the gate electrode 32, the planar shape of the gate wiring part 70 (the planar shape of the contact surface between the gate wiring part 70 and the gate electrode 32) has a mesh shape or a lattice shape. The entire gate wiring part 70 may overlap the gate trench TR2 or the gate electrode 32 when viewed in plan.

More specifically, in the example, the gate wiring part 70 includes multiple first wiring parts 71 and multiple second wiring parts 72. The gate wiring part 70 has a lattice shape in which the first wiring parts 71 and the second wiring parts 72 cross each other.

The first wiring part 71 extends along the first extension part 61 above the first extension part 61. In other words, the first wiring part 71 is positioned above the gate electrode 32 inside the first extension part 61 and extends in the second arrangement direction D2.

The second wiring part 72 extends along the second extension part 62 above the second extension part 62. In other words, the second wiring part 72 is positioned above the gate electrode 32 inside the second extension part 62 and extends in the first arrangement direction D1.

When viewed in plan, one FP electrode 31 is surrounded with a square formed of two adjacent first wiring parts 71 and two adjacent second wiring parts 72; and the FP contact 36 is located at the center of the square.

The gate wiring part 70 is finer than the gate trench TR2. For example, as illustrated in FIG. 3, a width W71 (the length in the direction perpendicular to the first arrangement direction D1) of the first wiring part 71 is less than the width W61 of the first extension part 61. For example, a width W72 (the length in the direction perpendicular to the second arrangement direction D2) of the second wiring part 72 is less than the width W62 of the second extension part 62. The width W62 may be equal to the width W61.

For example, the width of the gate wiring part 70 is less than the width of the gate electrode 32. The width of the gate wiring part 70 is not limited thereto; the width of the gate wiring part 70 may be equal to the width of the gate electrode 32 or greater than the width of the gate electrode 32. The width of the gate trench TR2 (the width W61 of the first extension part 61 and the width W62 of the second extension part 62) may be less than the width (the length in the first arrangement direction D1 or the second arrangement direction D2) of the FP trench TR1. The width of the gate electrode 32 inside the first extension part 61 or the second extension part 62 may be less than the width of the FP electrode 31.

As illustrated in FIG. 3, the planar shape of the region surrounded with the gate trench TR2 is a square with rounded corners; and the planar shape of the outer edge of the source contact 38 also is a square with rounded corners. In other words, the outer edge of the source contact 38 extends along the gate trench TR2 so that the distance from the gate trench TR2 is constant when viewed in plan. In other words, the width of the source region 23 is substantially constant. As a result, for example, bias of the transistor characteristics in the plane can be suppressed. The source contacts 38 have tubular shapes; and the FP contacts 36 are located inside the tubular shapes.

As illustrated in FIG. 2, the insulating layer 80 extends along the gate wiring part 70 over the gate wiring part 70. For example, similarly to the planar shape of the gate wiring part 70, the planar shape of the insulating layer 80 is a mesh shape or a lattice shape.

More specifically, in the example, the insulating layer 80 includes multiple first parts 81 and multiple second parts 82. The insulating layer 80 has a lattice shape in which the first parts 81 and the second parts 82 cross each other.

For example, the first part 81 extends in the second arrangement direction D2 along the first wiring part 71 above the first wiring part 71.

For example, the second part 82 extends in the first arrangement direction D1 along the second wiring part 72 above the second wiring part 72.

The width of the insulating layer 80 is greater than the width of the gate wiring part 70 and greater than the width of the gate trench TR2. For example, a width W81 (the length in the direction perpendicular to the first arrangement direction D1) of the first part 81 of the insulating layer 80 is greater than the width W71 of the first wiring part 71 (see FIG. 3) and greater than the width W61 of the first extension part 61 (see FIG. 3). A width W82 (the length in the direction perpendicular to the second arrangement direction D2) of the second part 82 of the insulating layer 80 may be equal to the width W81. Thus, the insulating layer 80 overlaps the entire gate trench TR2 and the entire gate wiring part 70 in the Z-direction. As a result, the gate wiring part 70 and the source electrode 12 can be more reliably insulated. When viewed in plan in FIG. 2, the source contact 38 and the FP trench TR1 are located inside each square opening provided in the insulating layer 80.

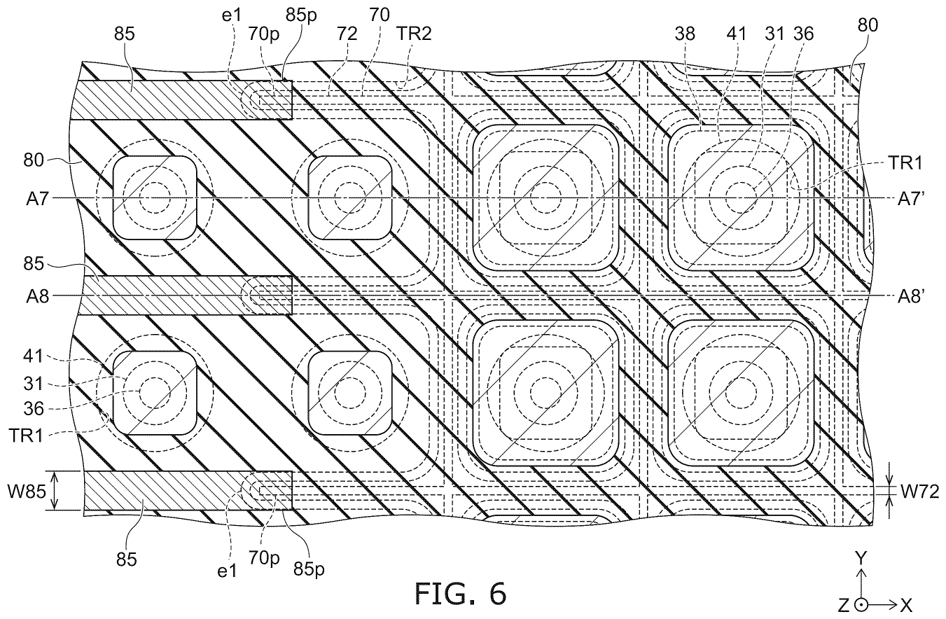

FIGS. 6 to 9 are schematic views illustrating the semiconductor device according to the embodiment.

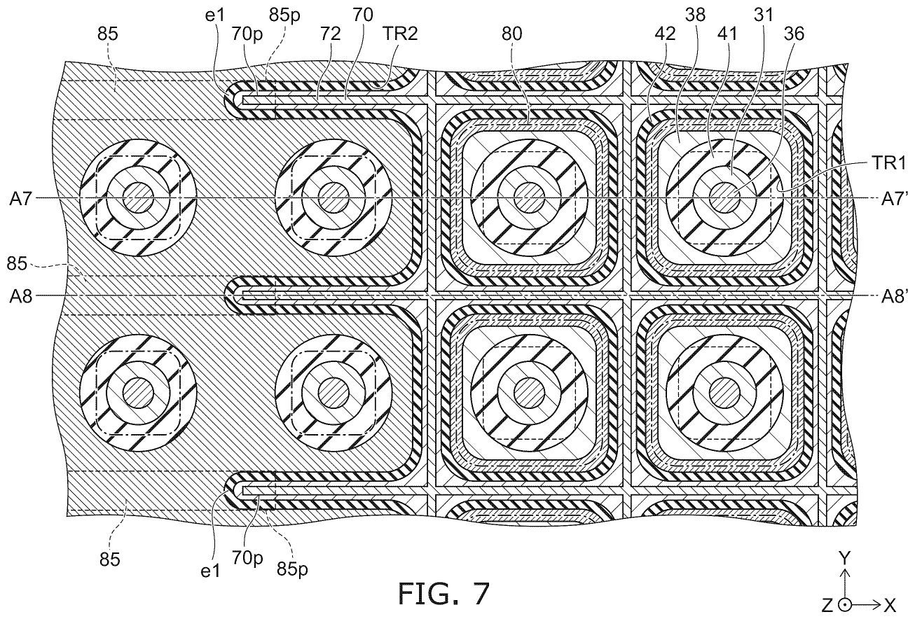

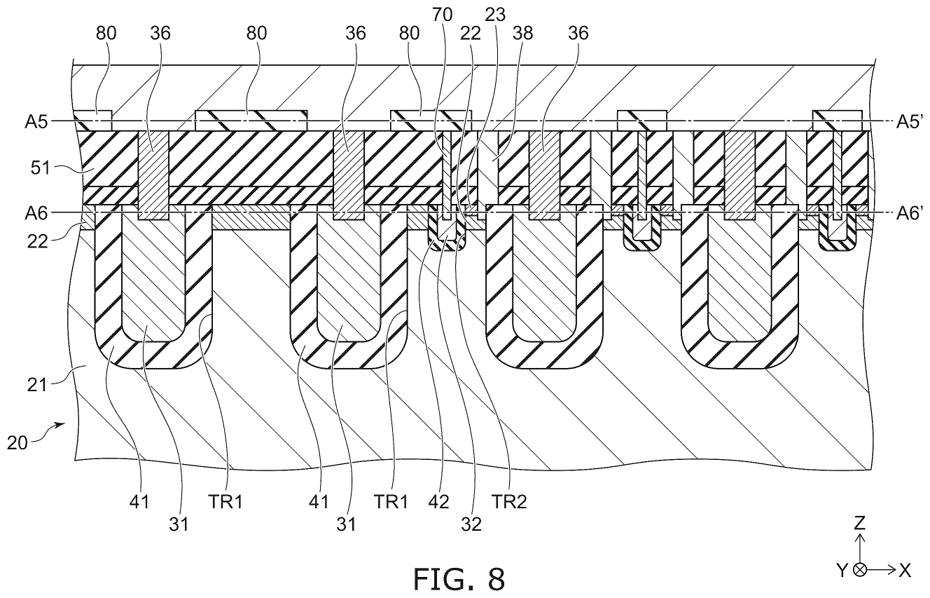

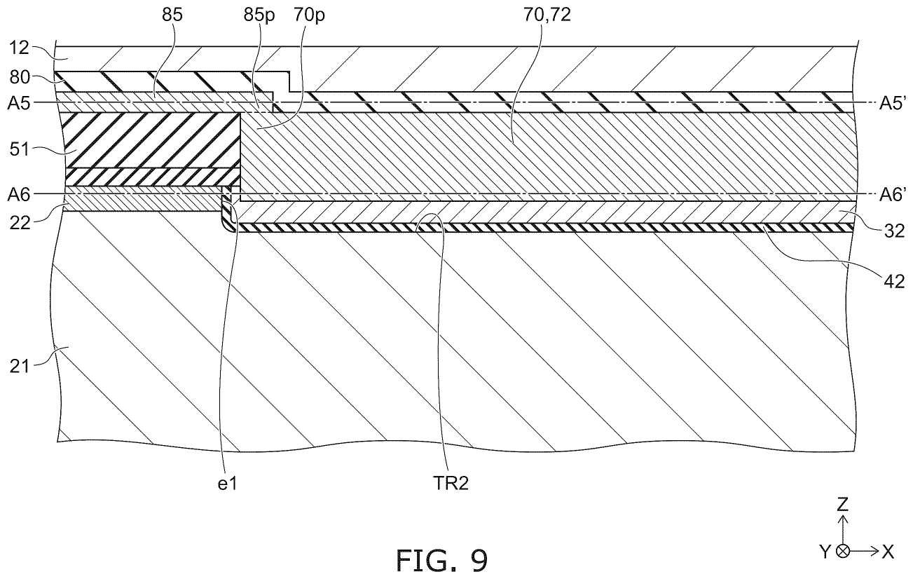

FIGS. 6 to 9 illustrate the structure of the end part (a region R2 illustrated in FIG. 1) inside the cell region RC. FIGS. 6 and 7 illustrate the planar layout. The hatching of FIG. 6 corresponds to a cross section along line A5-A5′ shown in FIGS. 8 and 9; and the hatching of FIG. 7 corresponds to a cross section along line A6-A6′ shown in FIGS. 8 and 9. FIG. 8 illustrates a cross section along line A7-A7′ shown in FIGS. 6 and 7. FIG. 9 illustrates a cross section along line A8-A8′ shown in FIGS. 6 and 7.

For example, the entire gate trench TR2 is located inside the cell region RC, and is not located outside the cell region RC. As illustrated in FIGS. 6 and 7, an end part e1 of the gate trench TR2 and an end part 70p of the gate wiring part 70 are positioned inside the cell region RC.

The semiconductor device 100 includes a draw-out wiring part 85 electrically connected with the gate wiring part 70. In the cell region RC, an end part 85p of the draw-out wiring part 85 is connected with the end part 70p of the gate wiring part 70. The draw-out wiring part 85 extends from the end part 85p contacting the gate wiring part 70 outside the cell region RC, that is, to the peripheral region RE (see FIG. 1).

Thus, a portion of the draw-out wiring part 85 is positioned further toward the peripheral region RE side than the gate trench TR2 and the gate wiring part 70 in the cell region RC, and extends toward the peripheral region RE. In the peripheral region RE, the draw-out wiring part 85 is electrically connected with the gate wiring part 14 positioned above the draw-out wiring part 85 (see FIG. 1). That is, the draw-out wiring part 85 electrically connects the gate wiring part 70 and the gate wiring part 14. The gate wiring part 70 can be drawn out to the peripheral region RE by the draw-out wiring part 85.

In the example illustrated in FIGS. 6 and 7, the end part 70p is the X-direction end part of the gate wiring part 70 (the second wiring part 72) extending in the X-direction; and the end part 85p is the X-direction end part of the draw-out wiring part 85 extending in the X-direction. The multiple draw-out wiring parts 85 are connected to the multiple second wiring parts 72. Although not illustrated, the draw-out wiring parts 85 that extend in the Y-direction from the Y-direction end parts of the gate wiring parts 70 (the first wiring parts 71) may be included.

For example, as illustrated in FIG. 6, a width W85 of the draw-out wiring part 85 may be greater than the width of the gate wiring part 70 (the width W72 of the second wiring part 72). The gate resistance can be reduced by increasing the width W85 of the draw-out wiring part 85.

Inside the cell region RC, the FP electrode 31 also is located between two mutually-adjacent draw-out wiring parts 85 when viewed in plan. The source contact 38 is not provided between the two mutually-adjacent draw-out wiring parts 85; and the insulating layer 80 is located above a portion of the FP insulating part 41 as in FIG. 6.

As illustrated in FIG. 9, the draw-out wiring part 85 is located on the insulating layer 51. The end part 85p of the draw-out wiring part 85 is located on the end part 70p of the gate wiring part 70. In other words, in the example, the draw-out wiring part 85 is positioned higher than the entire gate wiring part 70. For example, the length (the thickness) in the Z-direction of the gate wiring part 70 is greater than the Z-direction length of the draw-out wiring part 85.

The insulating layer 80 is located on the draw-out wiring part 85. The insulating layer 80 covers and contacts the upper surface and side surface of the draw-out wiring part 85. The insulating layer 80 is positioned between the source electrode 12 and the draw-out wiring part 85. As a result, the source electrode 12 and the draw-out wiring part 85 are insulated from each other.

The draw-out wiring part 85 may be formed as a continuous body with the gate wiring part 70 from the same material as the gate wiring part 70. In other words, the gate wiring part 70 may be one part of one conductive part; and the draw-out wiring part 85 may be another part of the one conductive part.

Examples of materials of components of the semiconductor device 100 will now be described.

The semiconductor regions of the semiconductor layer 20 include silicon (Si), silicon carbide, gallium nitride, or gallium arsenide as a semiconductor material. When silicon is used as the semiconductor material, arsenic, phosphorus, or antimony can be used as an n-type impurity. Boron can be used as a p-type impurity. The semiconductor layer 20 is, for example, a semiconductor substrate such as a silicon substrate, etc.

The FP electrode 31 and the gate electrode 32 include a conductive material such as polysilicon, a metal, etc.

The FP insulating part 41, the gate insulating part 42, the insulating layer 51, and the insulating layer 80 include an insulating material such as silicon oxide, silicon nitride, etc.

The drain electrode 11, the source electrode 12, the gate wiring part 14, and the gate pad 13 include a metal such as A1 (aluminum), etc.

The gate wiring part 70, the source contact 38, and the FP contact 36 include at least one of a silicide or a metal material. The silicide includes at least one selected from the group consisting of Co (cobalt), W (tungsten), Ti (titanium), and Ni (nickel). A metal silicide such as CoSi, WSi, TiSi, NiSi, or the like is used as the silicide. The metal material includes at least one selected from the group consisting of Ti, TiN (titanium nitride), W, Cu (copper), and Al. By using the metal material, conductive parts having a lower resistance can be obtained. For example, the electrical resistivity of the gate wiring part 70, the source contact 38, or the FP contact 36 may be less than the electrical resistivity of the gate electrode 32 or the FP electrode 31. Conductive parts are easily formed by using a silicide. The material of the source contact 38 and the material of the FP contact 36 may be the same as the material of the gate wiring part 70.

Operations of the semiconductor device 100 will now be described.

A positive voltage is applied to the gate pad 13 in a state in which a positive voltage with respect to the source electrode 12 is applied to the drain electrode 11. As a result, the voltage is applied from the gate pad 13 to the gate electrode 32 via the gate wiring part 14, the draw-out wiring part 85, and the gate wiring part 70. When a voltage that is greater than a threshold is applied to the gate electrode 32, an inversion layer is formed in the base region 22; and the transistor is switched on. In other words, an on-current flows from the drain electrode 11 to the source electrode 12 via the drift region 21, the base region 22, the source region 23, and the source contact 38. When the voltage of the gate pad 13 is reduced and the voltage of the gate electrode 32 reaches or drops below the threshold, the transistor is switched off, and the on-current does not flow.

In the semiconductor device 100 according to the embodiment as described above, the gate wiring part 70 is located inside the insulating layer 51 inside the cell region RC. The gate wiring part 70 extends along the gate electrode 32 over the gate electrode 32, and is electrically connected with the gate electrode 32. By including the gate wiring part 70, the gate resistance of the semiconductor device 100 can be reduced.

For example, as a semiconductor device of a reference example, a configuration may be considered in which the gate wiring part 14 and the gate electrode 32 are connected in the peripheral region RE without including the gate wiring part 70 inside the cell region RC. In contrast, according to the embodiment, by including the gate wiring part 70, for example, the current inside the cell region RC flows through a path in which the gate wiring part 70 and the gate electrode 32 are connected in parallel. As a result, the gate resistance of the embodiment can be reduced compared to the reference example.

A reference example may be considered in which efforts are made in the chip layout design to reduce the gate resistance by increasing the gate wiring parts 14. When, however, the gate wiring parts 14 are increased, the effective device area for the same chip size is reduced, and the area efficiency degrades. Also, it may be considered to reduce the gate resistance by using a metal gate in which the gate electrode is formed of a metal material. However, in the case of a metal gate, there is a risk that characteristics such as breakdown voltage, leakage current, defect density, etc., may be degraded by damage of the gate insulating film, etc., in the manufacturing processes. There are cases where the manufacturing processes become complex for a metal gate.

In contrast, according to the embodiment, the gate resistance can be reduced by including the gate wiring part 70 as described above. For example, by using polysilicon as the material of the gate electrode 32 and by including the gate wiring part 70, the gate resistance can be reduced while avoiding characteristic degradation and/or higher complexity of the manufacturing processes due to the metal gate. However, according to the embodiment, a metal material also can be used as the gate electrode 32.

The gate resistance can be reduced by widening the gate electrode 32. When, however, the width of the gate electrode 32 is increased, there are cases where the capacitance between the gate electrode 32 and the drain electrode 11 or the like is increased, and the reverse transfer capacitance of the transistor is increased. For example, in a structure in which the gate electrode 32 and the FP electrode 31 are located in separate trenches, there are cases where the reverse transfer capacitance is easily increased by widening the gate electrode 32 compared to a configuration in which the gate electrode 32 and the FP electrode 31 are located in the same trench. In contrast, in a configuration in which the gate electrode 32 and the FP electrode 31 are located in separate trenches, the gate resistance can be reduced while suppressing an increase of the reverse transfer capacitance by including the gate wiring part 70.

The gate wiring part 70 is finer than the gate trench TR2. By making the gate wiring part 70 fine, the distance between the gate wiring part 70 and the source region 23 can be ensured. As a result, for example, by including the gate wiring part 70, degradation of the transistor characteristics due to defects or the like in the insulating layers and/or the semiconductor layers can be suppressed.

For example, the length (the thickness) in the Z-direction of the gate wiring part 70 is greater than the width of the gate wiring part 70 (the width W71 or the width W72 described with reference to FIG. 3) and greater than the Z-direction length of the insulating layer 80. By making the gate wiring part 70 thick, the gate resistance can be further reduced while making the gate wiring part 70 fine. For example, as illustrated in FIG. 4, the width of the gate wiring part 70 may be less than a width W36 (the diameter) of the FP contact 36 or a width W38 of the source contact 38.

The insulating layer 80 is located on the gate wiring part 70; and the source electrode 12 is located on the insulating layer 80. Thus, by providing the gate wiring part 70 and the source electrode 12 in separate layers, the gate wiring part 70 can extend more widely inside the cell region RC. For example, as described above, the gate wiring part 70 has a lattice shape in which the first wiring part 71 and the second wiring part 72 that are along the gate trench TR2 and the gate electrode 32 cross each other. As a result, the gate resistance can be further reduced, and the gate wiring part 70 can be drawn out in two directions.

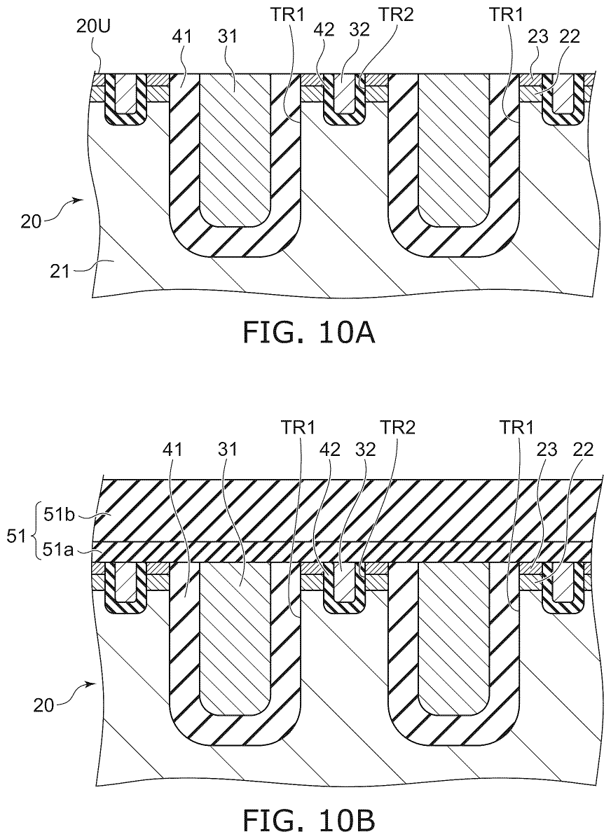

FIGS. 10A to 12B are schematic cross-sectional views illustrating a method for manufacturing the semiconductor device according to the embodiment.

As illustrated in FIG. 10A, for example, the FP trench TR1 and the gate trench TR2 are provided in the upper surface 20U of the semiconductor layer 20 by RIE (reactive ion etching). The FP insulating part 41 is formed inside the FP trench TR1; and the FP electrode 31 is formed at the inner side of the FP insulating part 41. The gate insulating part 42 is formed inside the gate trench TR2; and the gate electrode 32 is formed at the inner side of the gate insulating part 42. The base region 22 and/or the source region 23 are formed by ion implantation before forming (or after forming) the FP trench TR1 and the gate trench TR2.

Subsequently, as illustrated in FIG. 10B, the insulating layer 51 is formed on the semiconductor layer 20, the FP electrode 31, and the gate electrode 32. For example, a SiN layer is deposited as the first layer 51a; and a SiO₂ layer is deposited as the second layer 51b on the first layer 51a. Subsequently, the upper surface of the insulating layer 51 is planarized by CMP (chemical mechanical polishing).

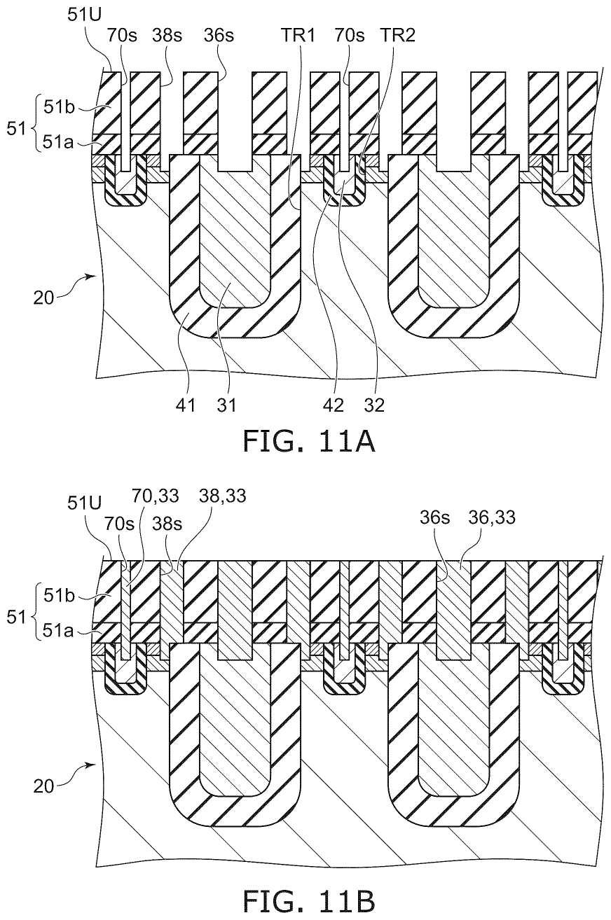

A resist is coated onto the insulating layer 51; and patterning by photolithography is performed. Through-holes are formed in the insulating layer 51 by RIE using the resist as a mask. Specifically, as illustrated in FIG. 11A, a first through-hole 70s (a slit), a second through-hole 38s, and a third through-hole 36s are simultaneously formed in the insulating layer 51.

The first through-hole 70s extends along the gate electrode 32, is finer than the gate trench TR2, and reaches the gate electrode 32 from an upper surface 51U of the insulating layer 51. The second through-hole 38s reaches the base region 22 from the upper surface 51U of the insulating layer 51 above the base region 22. The third through-hole 36s reaches the FP electrode 31 from the upper surface 51U of the insulating layer 51 above the FP electrode 31.

Subsequently, a conductive film 33 that is used to form the gate wiring part 70, the source contact 38, and the FP contact 36 illustrated in FIG. 11B is deposited on the insulating layer 51 (on the upper surface 51U, inside the first through-hole 70s, inside the second through-hole 38s, and inside the third through-hole 36s). The conductive film 33 includes, for example, a stacked film of TiN and W. Then, a portion of the conductive film 33 formed on the upper surface 51U of the insulating layer 51 is removed by, for example, RIE to expose the upper surface 51U. As a result, as illustrated in FIG. 11B, a portion of the conductive film 33 remains as the gate wiring part 70 inside the first through-hole 70s. A portion of the conductive film 33 remains as the source contact 38 inside the second through-hole 38s. A portion of the conductive film 33 remains as the FP contact 36 inside the third through-hole 36s.

Although not illustrated, a mask (a resist patterned by photolithography) is formed beforehand on a portion of the conductive film 33 before performing RIE of the conductive film 33. As a result, the conductive film 33 that remains on the upper surface 51U of the insulating layer 51 becomes the draw-out wiring part 85.

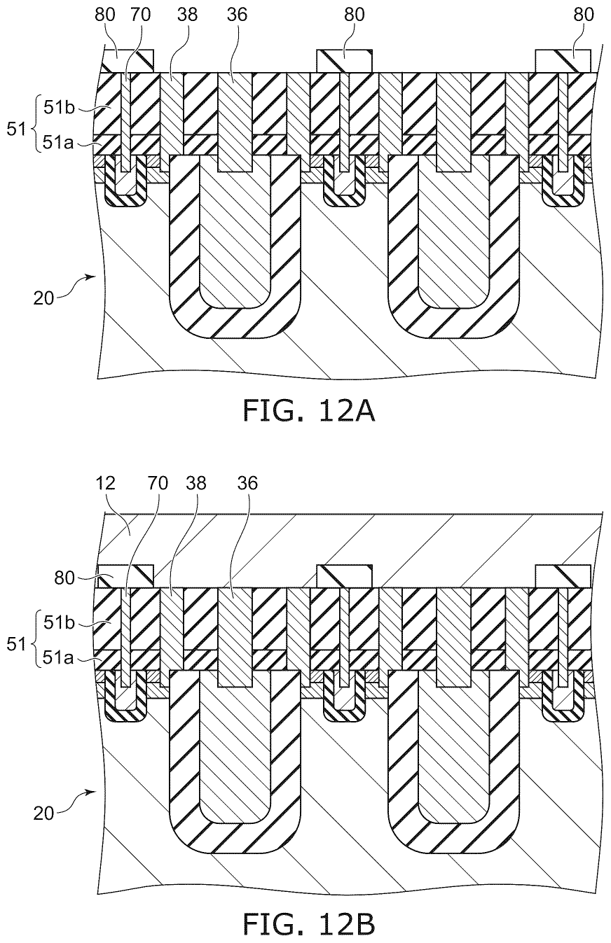

Subsequently, a silicon oxide layer that is used to form the insulating layer 80 illustrated in FIG. 12A is deposited on the insulating layer 51. A portion of the silicon oxide layer on the source contact 38 and the FP contact 36 is removed by photolithography and RIE. As a result, the insulating layer 80 is formed on the insulating layer 51 and the gate wiring part 70 (and the draw-out wiring part 85).

As illustrated in FIG. 12B, the source electrode 12 is formed by, for example, sputtering on the insulating layers 51 and 80.

Thus, the first through-hole 70s (the slit), the second through-hole 38s, and the third through-hole 36s can be simultaneously formed. By filling the conductive film 33 into these through-holes, the gate wiring part 70, the source contact 38, the FP contact 36, and the draw-out wiring part 85 can be simultaneously formed from the same conductive film 33. The number of processes can be reduced, and the semiconductor device can be manufactured by a simple method. When such a manufacturing method is used, for example, as described above, the height of the upper end of the gate wiring part 70 is equal to the heights of the upper ends of the source contact 38 and/or the FP contact 36.

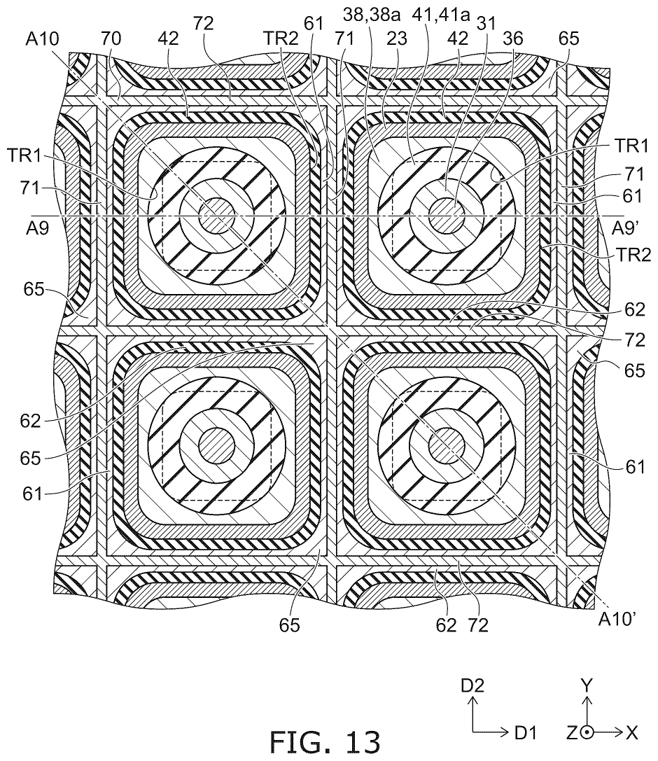

FIGS. 13 to 15 are schematic views illustrating a semiconductor device according to a modification of the embodiment.

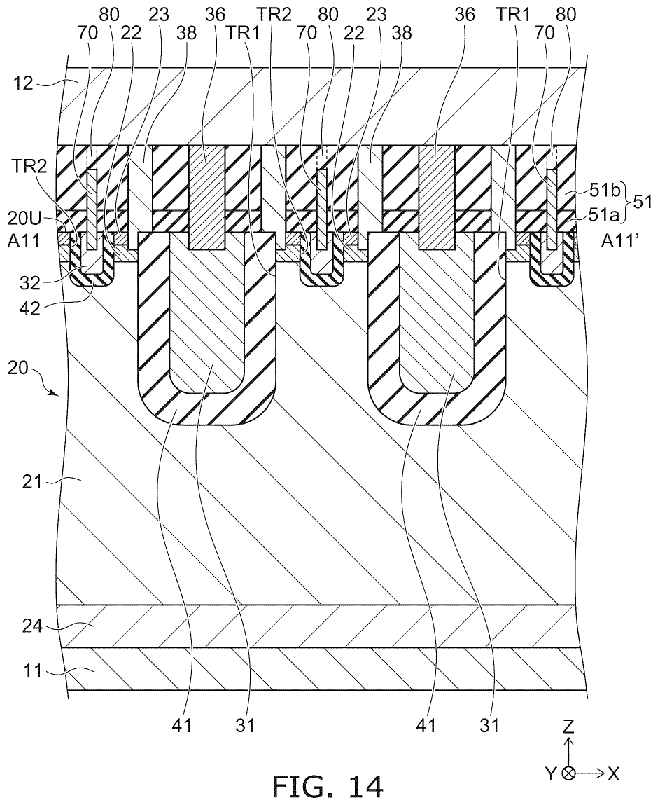

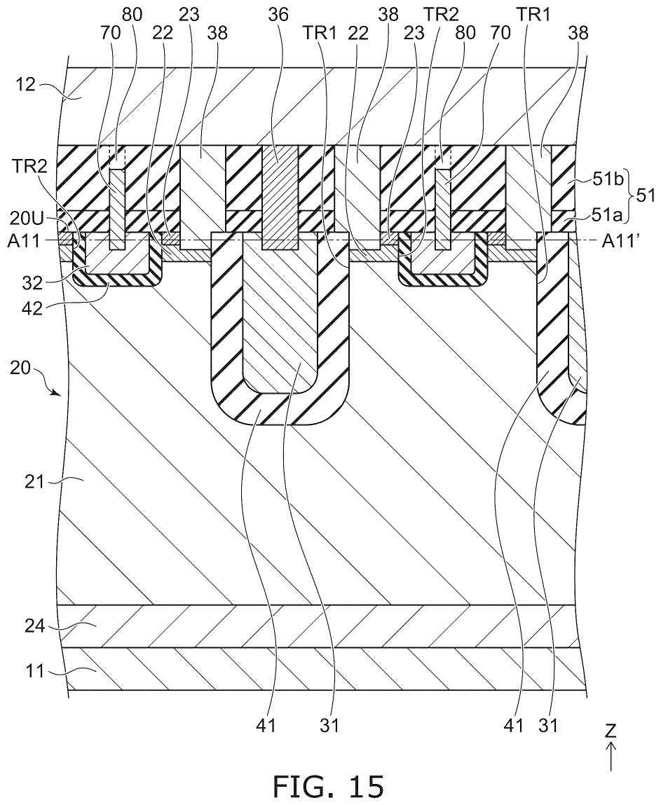

Similarly to FIG. 3, FIG. 13 illustrates a planar layout of the semiconductor device of the modification. The hatching of FIG. 13 corresponds to a cross section along line A11-A11′ shown in FIGS. 14 and 15. FIG. 14 illustrates a cross section along line A9-A9′ shown in FIG. 13. FIG. 15 illustrates a cross section along line A10-A10′ shown in FIG. 13.

According to the modification, the semiconductor device 100 described with reference to FIGS. 1 to 9 has a structure in which the insulating layer 80 on the gate wiring part 70 is filled into the slit of the insulating layer 51. In other words, for example, as illustrated in FIG. 14 or FIG. 15, the insulating layer 51 is positioned at the side of the gate wiring part 70 and the insulating layer 80. In other words, the insulating layer 51 is arranged with the gate wiring part 70 and the insulating layer 80 in lateral directions (directions perpendicular to the Z-direction). The width of the insulating layer 80 may be equal to the width of the gate wiring part 70.

The height (the Z-direction position) of the upper surface of the insulating layer 51 is equal to the height of the upper surface of the insulating layer 80. The upper surface of the insulating layer 51 and the upper surface of the insulating layer 80 are coplanar and extend along the X-Y plane. The height of the upper end of the source contact 38 and the height of the upper end of the FP contact 36 may be equal to the height of the upper surface of the insulating layer 51. The source electrode 12 is located on the insulating layers 51 and 80 in contact with the insulating layers 51 and 80. The height of the upper end of the gate wiring part 70 is less than the height of the upper end of the source contact 38 and the height of the upper end of the FP contact 36.

Although the insulating layer 51 and the insulating layer 80 are described as separate layers for convenience, cases are included where the boundary between the insulating layer 51 and the insulating layer 80 cannot always be clearly observed. In other words, a configuration may be used in which the insulating layer 80 is formed as a portion of the insulating layer 51.

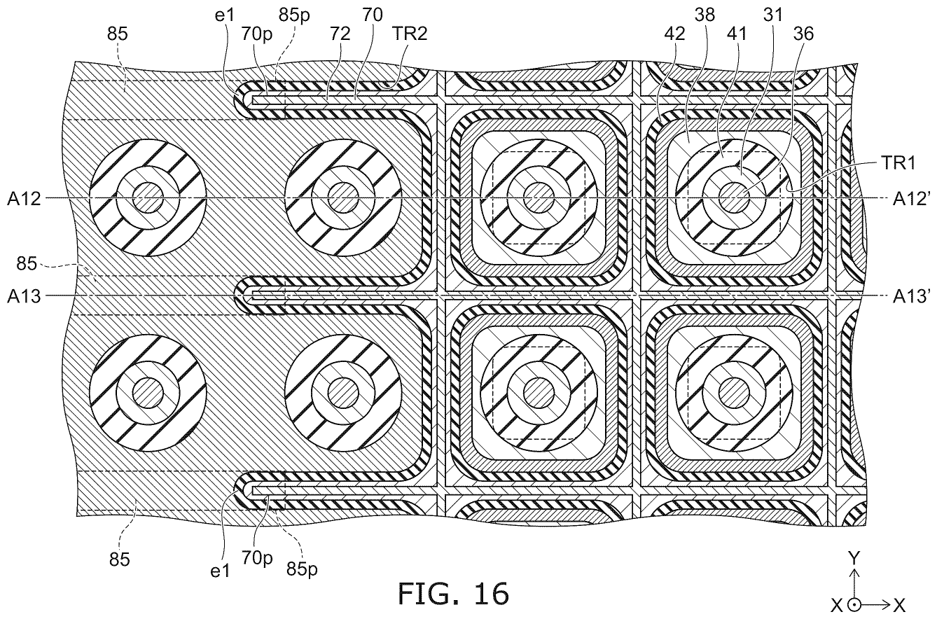

FIGS. 16 to 18 are schematic views illustrating the semiconductor device according to the modification of the embodiment.

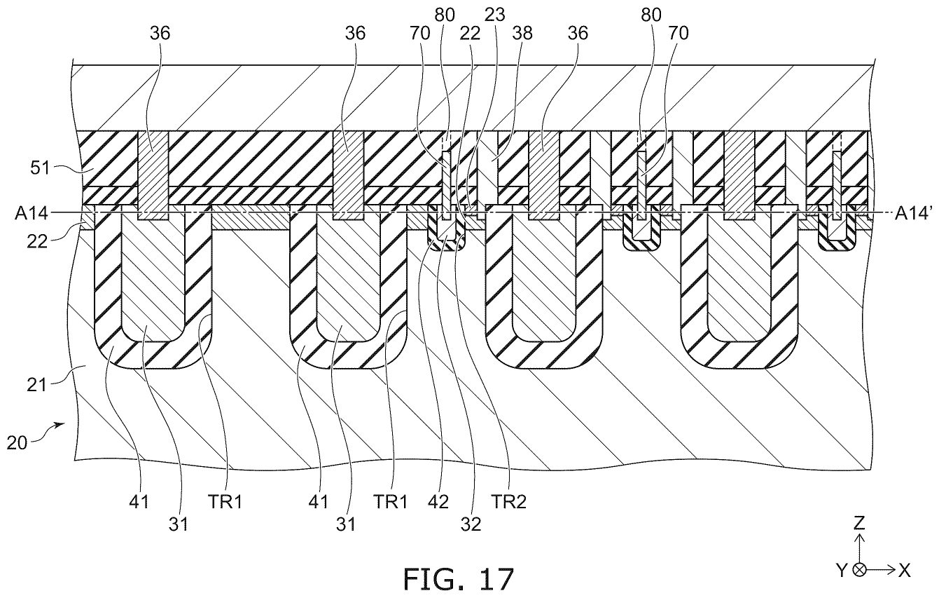

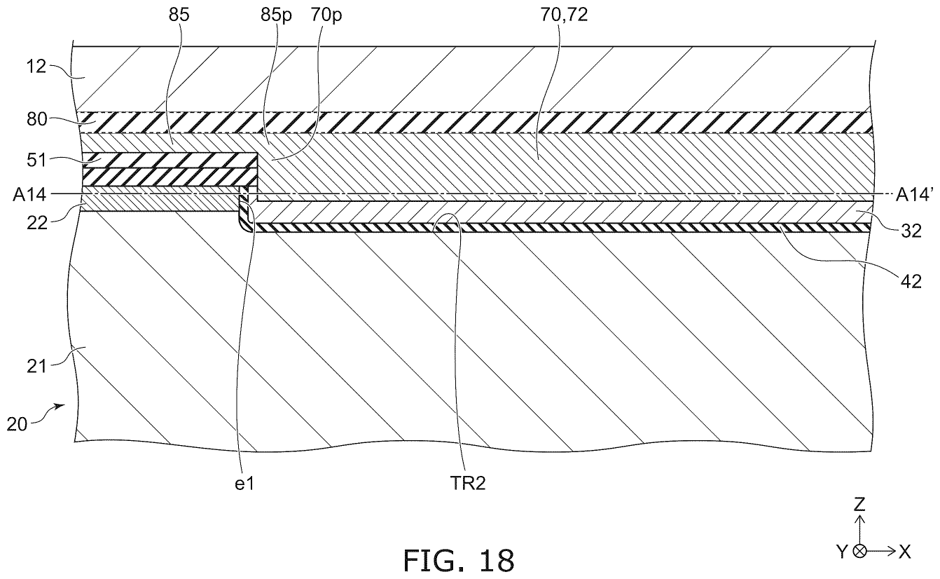

Similarly to FIG. 7, FIG. 16 illustrates a planar layout of the semiconductor device of the modification. The hatching of FIG. 16 corresponds to a cross section along line A14-A14′ shown in FIGS. 17 and 18. FIG. 17 illustrates a cross section along line A12-A12′ shown in FIG. 16. FIG. 18 illustrates a cross section along line A13-A13′ shown in FIG. 16.

In the example as illustrated in FIG. 18, the height (the Z-direction position) of the upper surface of the draw-out wiring part 85 is equal to the height of the upper surface of the gate wiring part 70. The upper surface of the draw-out wiring part 85 and the upper surface of the gate wiring part 70 are coplanar and extend along the X-Y plane. Therefore, the upper surface of the insulating layer 80 is substantially flat.

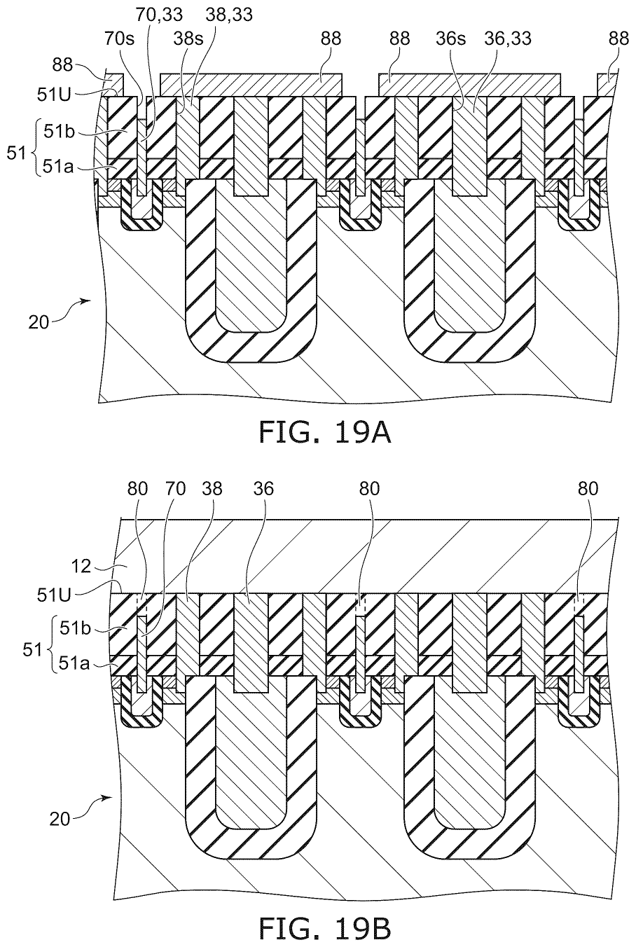

FIGS. 19A and 19B are schematic cross-sectional views illustrating a method for manufacturing the semiconductor device according to the modification.

When manufacturing the semiconductor device of the modification, similarly to FIGS. 10A and 10B, the semiconductor regions, the FP trench TR1, the gate trench TR2, the FP insulating part 41, the FP electrode, the gate insulating part 42, the gate electrode 32, and the insulating layer 51 are formed in the semiconductor layer 20.

Subsequently, similarly to FIGS. 11A and 11B, the first through-hole 70s, the second through-hole 38s, and the third through-hole 36s are formed; and the conductive film 33 is filled. Although not illustrated, a trench (called a wiring trench) into which the draw-out wiring part 85 is filled is formed in the insulating layer 51 to communicate with the first through-hole 70s by photolithography and/or RIE before filling the conductive film 33. The conductive film 33 also is deposited inside the wiring trench simultaneously with the first through-hole 70s, etc.

Subsequently, as illustrated in FIG. 19A, a resist 88 is formed on the insulating layer 51. In other words, the resist 88 is patterned by photolithography to cover the conductive film 33 inside the second through-hole 38s and the third through-hole 36s and to expose the conductive film 33 inside the first through-hole 70s (and the wiring trench). A portion of the conductive film 33 inside the upper portion of the first through-hole 70s (and inside the upper portion of the wiring trench) is removed by RIE using the patterned resist 88 as a mask. As in FIG. 19A, a portion of the conductive film 33 remaining inside the lower portion of the first through-hole 70s becomes the gate wiring part 70. A portion of the conductive film 33 remaining inside the lower portion of the wiring trench becomes the draw-out wiring part 85.

After removing the resist 88, the insulating layer 80 is deposited on the insulating layer 51 and inside the upper portion of the first through-hole 70s (and inside the upper portion of the wiring trench) from which the conductive film 33 was removed. Then, the insulating layer 80 is polished by CMP to expose the FP contact 36, the source contact 38, and the upper surface 51U of the insulating layer 51. Thus, as illustrated in FIG. 19B, the insulating layer 80 is filled into the upper portion of the first through-hole 70s (and into the upper portion of the wiring trench). Subsequently, the source electrode 12 is formed by sputtering on the insulating layer 51, the insulating layer 80, the FP contact 36, and the source contact 38.

Thus, similarly to the semiconductor layer described with reference to FIGS. 1 to 12B, according to the modification described with reference to FIGS. 13 to 19B as well, the gate resistance can be reduced by including the gate wiring part 70. According to the modification, the insulating layer 80 is filled into the insulating layer 51; and a surface step can be suppressed. For example, the uniformity of the thickness of the source electrode 12 can be increased thereby.

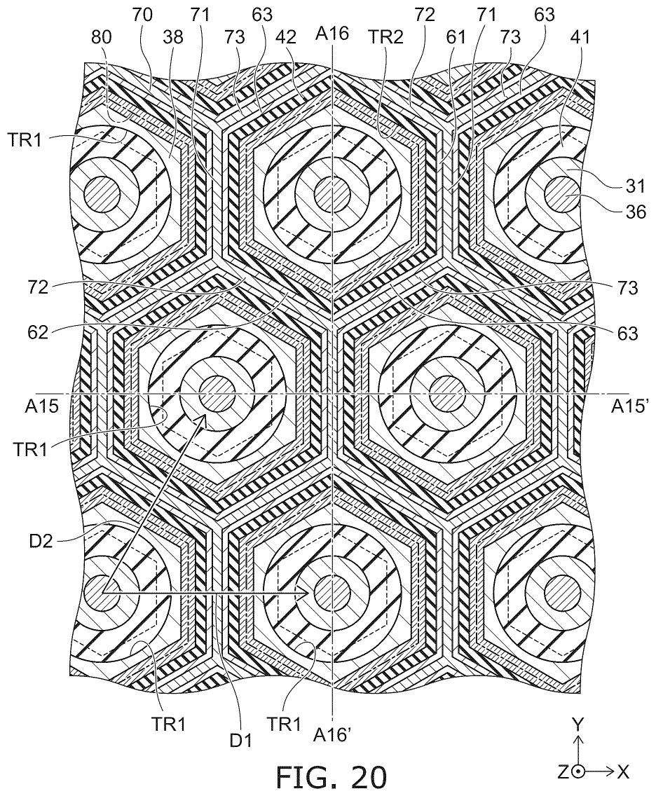

FIGS. 20 to 25 are schematic views illustrating another semiconductor device according to the embodiment.

Although not illustrated, similarly to FIG. 1 above, in the semiconductor device as well, the cell region RC in which the source electrode 12 is located is set, and the peripheral region RE in which the gate wiring part 14 and the gate pad 13 are located is set.

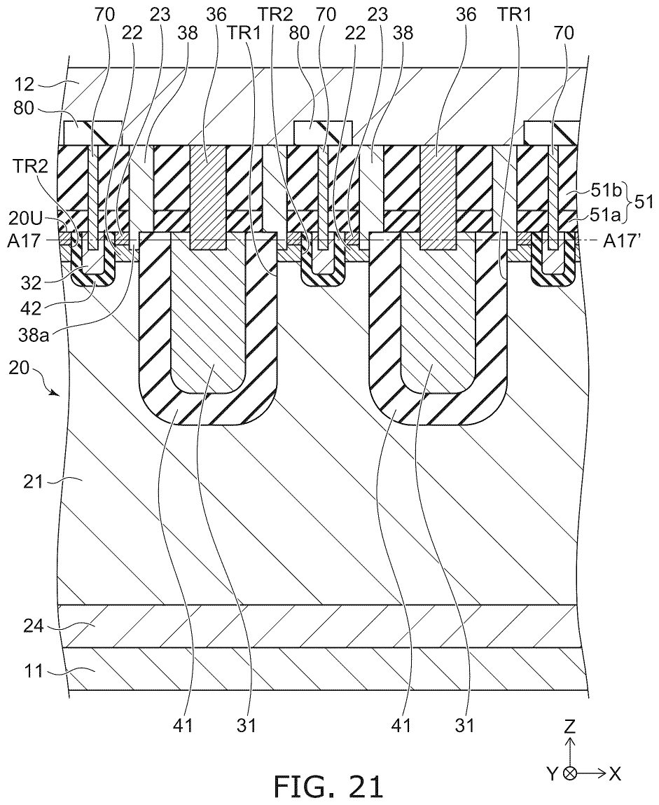

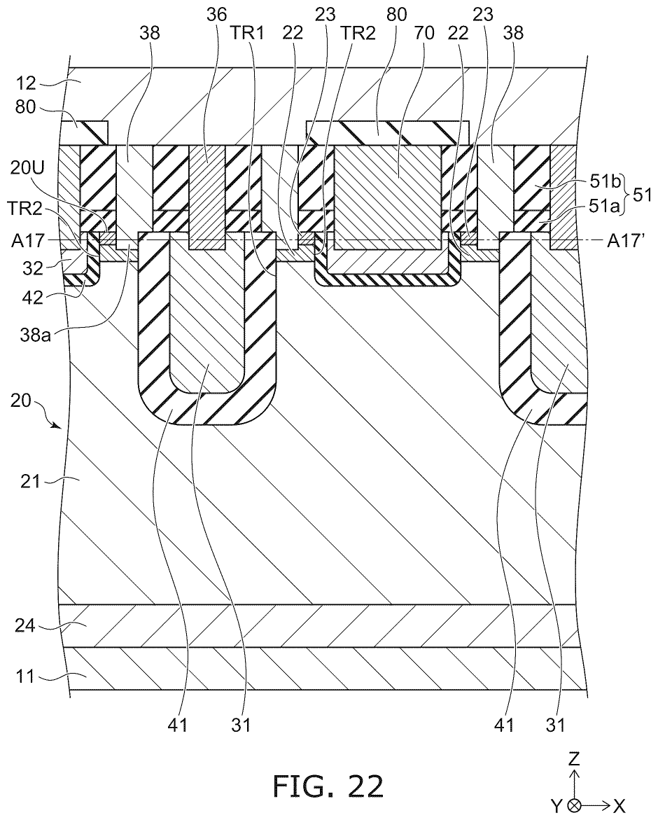

FIGS. 20 to 22 illustrate the structure of the central part of the cell region RC. FIG. 20 illustrates the planar layout. The hatching of FIG. 20 corresponds to a cross section along line A17-A17′ shown in FIGS. 21 and 22. FIG. 21 illustrates a cross section along line A15-A15′ shown in FIG. 20. FIG. 22 illustrates a cross section along line A16-A16′ shown in FIG. 20.

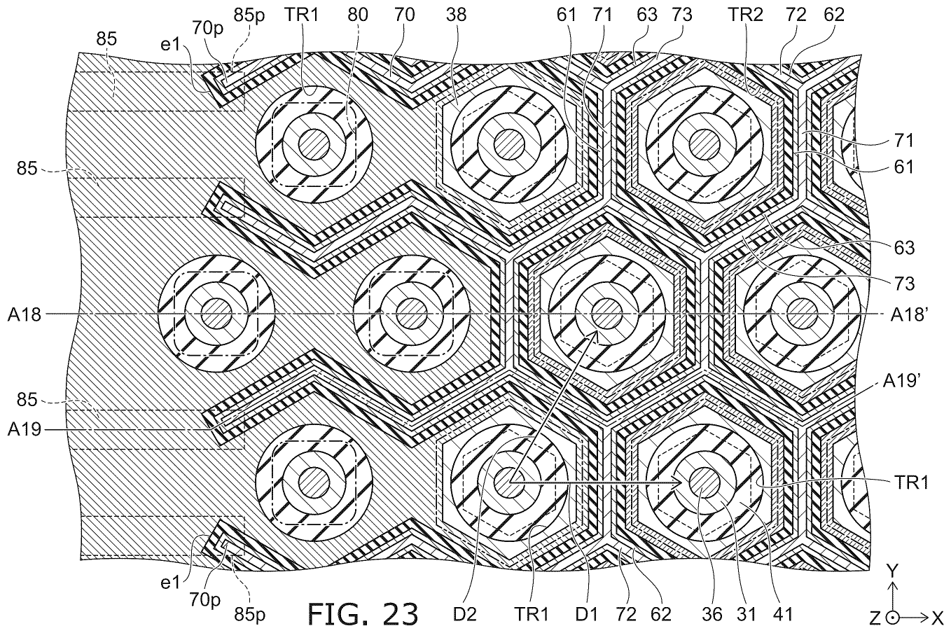

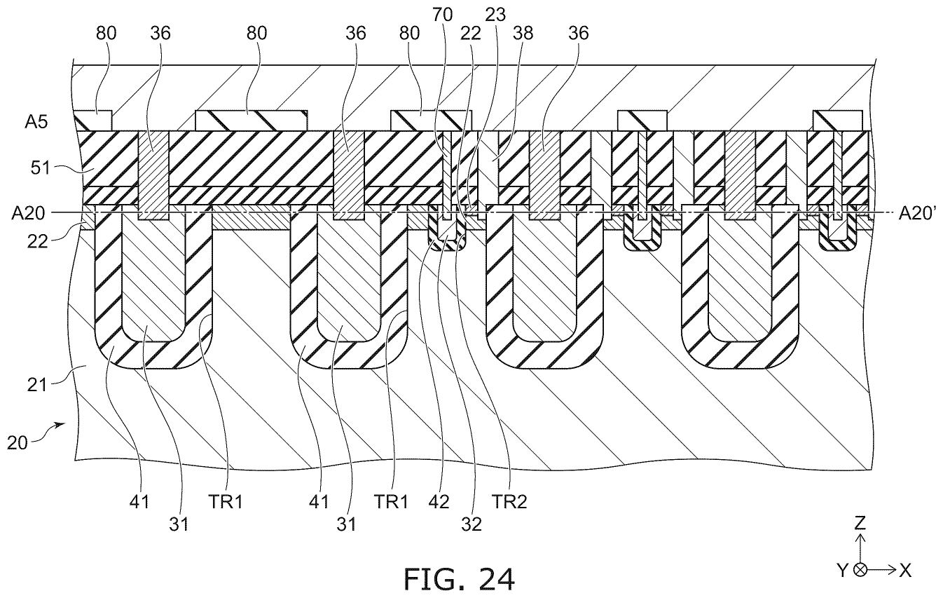

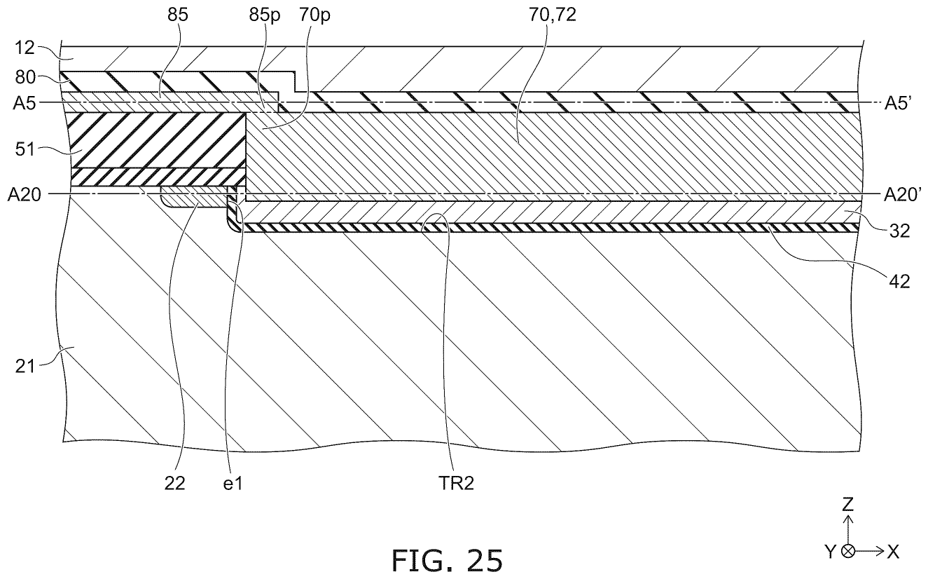

FIGS. 23 to 25 illustrate the structure of the end part inside the cell region RC. FIG. 23 illustrates the planar layout. The hatching of FIG. 23 corresponds to a cross section along line A20-A20′ shown in FIGS. 24 and 25. FIG. 24 illustrates a cross section along line A18-A18′ shown in FIG. 23. FIG. 25 illustrates a cross section along line A19-A19′ shown in FIG. 23. In the cell region RC as illustrated in FIG. 20 or FIG. 23, the multiple FP trenches TR1 are arranged in the first and second arrangement directions D1 and D2 in the X-Y plane. In the example, the first arrangement direction D1 is the X-direction. The second arrangement direction D2 is a direction oblique to the first arrangement direction D1. For example, the angle between the first arrangement direction D1 and the second arrangement direction D2 is 60°. In the example, the multiple FP electrodes 31 are positioned at vertices of triangles (e.g., equilateral triangles) when viewed in plan.

The gate trench TR2 includes the first extension part 61, the second extension part 62, and a third extension part 63. The first extension part 61 extends in the Y-direction (the direction perpendicular to the first arrangement direction D1). The second extension part 62 extends in the direction perpendicular to the second arrangement direction D2. The third extension part 63 extends in a different direction from the first and second extension parts 61 and 62.

The planar shape of the gate trench TR2 is a mesh shape in which hexagons (e.g., regular hexagons) are arranged. In other words, two first extension parts 61, two second extension parts 62, and two third extension parts 63 are positioned at the six sides of the hexagon. The first extension part 61, the second extension part 62, and the third extension part 63 are connected at each vertex of the hexagon. One FP trench TR1 is located inside the hexagon; and the FP electrode 31 is positioned at the center of the hexagon. The hexagon that is formed of the gate trench TR2 may be a hexagon with rounded corners (vertices). For example, the planar shape of the region surrounded with the first extension part 61, the second extension part 62, the third extension part 63, and the connection part of the first, second, and third extension parts 61, 62, and 63 may be a regular hexagon with rounded corners. Similarly to the gate trench TR2, the gate electrode 32 has a mesh shape in which the hexagons are repeated.

The gate wiring part 70 includes the first wiring part 71, the second wiring part 72, and a third wiring part 73. The first wiring part 71 extends along the first extension part 61 above the first extension part 61 of the gate trench TR2. The second wiring part 72 extends along the second extension part 62 above the second extension part 62 of the gate trench TR2. The third wiring part 73 extends along the third extension part 63 above the third extension part 63 of the gate trench TR2. In other words, the planar shape of the gate wiring part 70 is a mesh shape in which the hexagons are arranged. Two first wiring parts 71, two second wiring parts 72, and two third wiring parts 73 are positioned at the six sides of the hexagon.

The insulating layer 80 extends along the first, second, and third wiring parts 71, 72, and 73 on the first, second, and third wiring parts 71, 72, and 73. In other words, similarly to the gate wiring part 70, the insulating layer 80 includes a mesh-shaped part in which the hexagons are arranged when viewed in plan.

Thus, the multiple FP electrodes 31 may be located on triangles. In the example as well, similarly to the semiconductor device described above, the gate resistance can be reduced by including the gate wiring part 70.

According to embodiments, a semiconductor device and a method for manufacturing a semiconductor device can be provided in which the gate resistance can be reduced.

In this specification, being “electrically connected” includes not only the case of being connected in direct contact, but also the case of being connected via another conductive member, etc.

The relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. Also, the impurity concentration in each semiconductor region can be measured by, for example, SIMS (secondary ion mass spectrometry).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first electrode;
a second electrode positioned above the first electrode;
a semiconductor layer located between the first electrode and the second electrode, the semiconductor layer including
a first semiconductor region of a first conductivity type,
a second semiconductor region located on the first semiconductor region, the second semiconductor region being of a second conductivity type, and
a third semiconductor region located on the second semiconductor region, the third semiconductor region being electrically connected with the second electrode, the third semiconductor region being of the first conductivity type;
a plurality of third electrodes arranged in a cell region in which the second electrode is located, the plurality of third electrodes facing the first semiconductor region via a first insulating part;
a fourth electrode including a part positioned between two mutually-adjacent third electrodes among the plurality of third electrodes, the fourth electrode facing the second semiconductor region via a second insulating part;
a first insulating layer located on the semiconductor layer; and
a wiring part located inside the first insulating layer in the cell region, the wiring part extending along the fourth electrode over the fourth electrode, the wiring part being finer than the fourth electrode, the wiring part being electrically connected with the fourth electrode.

2. The device according to claim 1, further comprising:
a second insulating layer covering an upper end of the wiring part,
the second electrode being located on the second insulating layer and insulated from the wiring part by the second insulating layer.

3. The device according to claim 2, wherein
the first insulating layer includes a slit,
the wiring part is located inside the slit, and
the second insulating layer is located on the upper end of the wiring part and on an upper surface of the first insulating layer.

4. The device according to claim 3, wherein
the second insulating layer extends along the wiring part over the wiring part.

5. The device according to claim 3, further comprising:
a first contact positioned on the third electrode, the first contact electrically connecting the third electrode and the second electrode; and
a second contact positioned on the second semiconductor region, the second contact electrically connecting the third semiconductor region and the second electrode,
a height of the upper end of the wiring part being equal to a height of an upper end of the first contact.

6. The device according to claim 2, wherein
the first insulating layer is arranged with the wiring part and the second insulating layer in a direction perpendicular to a first direction,
the first direction is from the first electrode toward the second electrode,
a height of an upper surface of the first insulating layer is equal to a height of an upper surface of the second insulating layer, and
the second electrode is located on the first and second insulating layers.

7. The device according to claim 6, further comprising:
a first contact positioned on the third electrode, the first contact electrically connecting the third electrode and the second electrode; and
a second contact positioned on the second semiconductor region, the second contact electrically connecting the third semiconductor region and the second electrode,
a height of the upper end of the wiring part being less than a height of an upper end of the first contact.

8. The device according to claim 1, further comprising:
a draw-out wiring part located on the first insulating layer,
the draw-out wiring part being electrically connected with the wiring part,
the fourth electrode being located in the cell region,
the draw-out wiring part extending outside the cell region.

9. The device according to claim 1, wherein
a length of the wiring part in a first direction is greater than a width of the wiring part, and
the first direction is from the first electrode toward the second electrode.

10. The device according to claim 5, wherein
a width of the wiring part is less than a width of the first contact.

11. The device according to claim 1, wherein
the plurality of third electrodes is arranged in a first arrangement direction and a second arrangement direction,
the first arrangement direction and the second arrangement direction cross each other,
the fourth electrode includes:
a first extension part positioned between two third electrodes among the plurality of third electrodes adjacent to each other in the first arrangement direction; and
a second extension part positioned between two third electrodes among the plurality of third electrodes adjacent to each other in the second arrangement direction, and
the wiring part includes:
a first wiring part extending along the first extension part above the first extension part; and
a second wiring part extending along the second extension part above the second extension part.

12. The device according to claim 11, wherein
the second arrangement direction is orthogonal to the first arrangement direction, and
the wiring part has a lattice shape in which the first wiring part and the second wiring part cross each other.

13. The device according to claim 1, wherein
the fourth electrode includes polysilicon,
the wiring part includes at least one of a silicide or a metal material,
the silicide includes at least one selected from the group consisting of Co, W, Ti, and Ni, and
the metal material includes at least one selected from the group consisting of Ti, TiN, W, Cu, and Al.

14. The device according to claim 1, further comprising:
a first contact positioned on the third electrode, the first contact electrically connecting the third electrode and the second electrode; and
a second contact positioned on the second semiconductor region, the second contact electrically connecting the third semiconductor region and the second electrode,
a material of the wiring part being the same as a material of the first contact and a material of the second contact.

15. The device according to claim 4, wherein
the second insulating layer has a mesh shape or a lattice shape.

16. The device according to claim 1, wherein
the second semiconductor region is positioned between the third electrode and the fourth electrode.

17. The device according to claim 1, wherein
the plurality of third electrodes is positioned at vertices of squares or at vertices of equilateral triangles.

18. A method for manufacturing a semiconductor device, the method comprising:
preparing a semiconductor layer, the semiconductor layer including a first semiconductor region of a first conductivity type, a second semiconductor region of a second conductivity type, and a third semiconductor region of the first conductivity type, the second semiconductor region being located on the first semiconductor region, the third semiconductor region being located on the second semiconductor region, the third semiconductor region being electrically connected with the second electrode, a plurality of first trenches and a second trench being formed in an upper surface of the semiconductor layer, the second trench including a part positioned between two mutually-adjacent first trenches among the plurality of first trenches, third electrodes being formed inside the first trenches with a first insulating part interposed, the third electrodes facing the first semiconductor region, a fourth electrode being formed inside the second trench with a second insulating part interposed, the fourth electrode facing the second semiconductor region;
forming a first insulating layer on the semiconductor layer, the third electrode, and the fourth electrode;
simultaneously forming, in the first insulating layer,
a first through-hole extending along the fourth electrode, the first through-hole being finer than the second trench, the first through-hole reaching the fourth electrode from an upper surface of the first insulating layer,
a second through-hole above the second semiconductor region, the second through-hole reaching the second semiconductor region from the upper surface of the first insulating layer, and
a third through-hole above the third electrode, the third through-hole reaching the third electrode from the upper surface of the first insulating layer,
forming a conductive film on the first insulating layer to form
a wiring part positioned inside the first through-hole, the wiring part being electrically connected with the fourth electrode,
a first contact positioned inside the third through-hole, the first contact being electrically connected with the third electrode, and
a second contact positioned inside the second through-hole, the second contact being electrically connected with the second semiconductor region;
forming a second insulating layer on the wiring part; and
forming the second electrode on the first and second insulating layers, the second electrode being insulated from the wiring part and electrically connected with the first and second contacts.

19. The method according to claim 18, wherein
the second insulating layer is formed on the first insulating layer and the wiring part.

20. The method according to claim 18, wherein
a portion of the conductive film formed inside an upper portion of the first through-hole is removed, and
the second insulating layer is formed inside the upper portion of the first through-hole.
